(19) United States
(12) Patent Application Publication
(10) Pub. No.: US 2016/0194784 A1
(43) Pub. Date: Jul. 7, 2016

(54) EPITAXIAL REACTOR

(71) Applicant: LG SILTRON INCORPORATED, Gyeongsangbuk-do (KR)

(72) Inventors: In Kyum KIM, Gumi-si, Gyeongsangbuk-do (KR); Yong Moon HUR, Gumi-si, Gyeongsangbuk-do (KR)

(21) Appl. No.: 14/910,175

(22) PCT Filed: Aug. 8, 2014
(86) PCT No.: PCT/KR2014/007362

§ 371 Date: Feb. 4, 2016

(30) Foreign Application Priority Data
Aug. 9, 2013 (KR) 10-2013-0094857

(51) Int. Cl. C30B 25/14; C23C 16/455; C30B 25/16

(52) U.S. Cl. CPC C30B 25/14; C30B 25/165; C23C 16/45563

(57) ABSTRACT

An embodiment comprises a reacting chamber; a susceptor which is located in the reacting chamber and seats a wafer therein; and a gas flow controller for controlling the flow of gas introduced in the reacting chamber, wherein the gas flow controller includes an inject cap having a plurality of gas outlets for separating the flow of gas and includes a plurality of baffles having through-holes corresponding to the plurality of gas outlets, respectively, and the plurality of baffles are separated from each other, and each of the baffles is disposed adjacently to a corresponding gas outlet among the plurality of gas outlets.

### TECHNICAL FIELD

Embodiments relate to an epitaxial reactor.

### BACKGROUND ART

Epitaxial reactors are classified into batch type epitaxial reactors and single wafer processing type epitaxial reactors, and these single wafer processing type epitaxial reactors are mainly used to manufacture epitaxial wafers having diameters of 200 mm or more.

Such a single wafer processing type epitaxial reactor is configured such that one wafer is seated on a susceptor in a reaction container, after which source gas is made to flow from one side of the reaction container to the other side thereof in a horizontal direction, thereby supplying the source gas to the surface of the wafer and growing an epilayer thereon.

In the single wafer processing type epitaxial reactor, the flow rate or flow distribution of source gas in the reaction container are critical factors for uniformizing the thickness of the layer growing on the surface of the wafer.

A typical epitaxial reactor may include a gas supply part for supplying source gas into a reaction container, and the flow rate or flow distribution of source gas in the reaction container may depend on the flow rate or flow distribution of the source gas supplied from the gas supply part.

In general, the gas supply part may include a baffle having therein a plurality of holes in order to supply source gas to the reaction container such that the source gas may uniformly flow on the surface of the wafer.

### DISCLOSURE

### Technical Problem

Embodiments provide an epitaxial reactor capable of minimizing the loss of source gas introduced into a reaction chamber and the formation of vortices therein, and of increasing the uniformity of thickness of a growing epilayer.

### Technical Solution

In accordance with an embodiment, an epitaxial reactor includes a reaction chamber, a susceptor located in the reaction chamber such that a wafer is seated thereon, and a gas flow controller for controlling a flow of gas introduced into the reaction chamber, wherein the gas flow controller includes an inject cap having a plurality of gas outlets for separating the flow of gas, and a plurality of baffles, each having through-holes corresponding to a respective one of the gas outlets, the baffles are separated from each other, and each of the baffles is disposed adjacent to a corresponding one of the gas outlets.

The inject cap may have a guide part protruding from one surface thereof to expose the gas outlets, and the baffles may be inserted into the guide part.

The guide part may have a ring shape so as to surround the gas outlets.

Each of the baffles may include a plate having therein the through-holes spaced apart from each other, and a support part connected to one surface of the plate, the support part may be inserted into each of the gas outlets, and the plate may be inserted into a guide part.

The support part may include a plurality of legs spaced apart from each other, and the legs may be inserted into the associated gas outlet.

An outer peripheral surface of the plate inserted into the guide part may be pressed against an inner wall of the guide part.

One end of the support part inserted into the gas outlet may be in contact with an inner bottom of the inject cap.

The plate may have a recessed groove(s) formed in one end or both ends thereof in a longitudinal direction of the plate, the groove formed in one end of one of two adjacent plates inserted into the guide part and the groove formed in one end of a remaining one thereof may be adjacent to each other, and the two adjacent grooves may form one coupling groove.

An upper surface of each of the baffles, configured such that one end of the support part comes into contact with the inner bottom of the inject cap, may be flush with an upper surface of the guide part.

An upper surface of each of the baffles, configured such that one end of the support part comes into contact with the inner bottom of the inject cap, may be located beneath an upper surface of the guide part, and a step may be present between the upper surface of each of the baffles and the upper surface of the guide part. The step may be less than 6 mm.

The inject cap may include at least two parts isolated from each other, and one of the gas outlets may foe provided in a corresponding one of the at least two parts.

The epitaxial reactor may further include an insert including a plurality of sections separated from each other so that the gas passing through the through-holes passes through the sections, and a liner having a stepped part in order to guide the gas passing through the sections to the reaction chamber.

The guide part may have a groove into which outer peripheral surfaces of the baffles are fixedly fitted.

The baffles may be inserted into the guide part such that each of the baffles is aligned with a corresponding one of the gas outlets.

The inject cap may have at least one coupling part formed at the other surface thereof.

The legs of one support part of the baffles may have different lengths from those of remaining support parts of the baffles.

### Advantageous Effects

Embodiments can minimize the loss of source gas introduced into a reaction chamber and the formation of vortices therein, and can increase the uniformity of thickness of a growing epilayer.

### DESCRIPTION OF DRAWINGS

FIG. 1 is a cross-sectional view illustrating an epitaxial reactor according to an embodiment.

FIG. 2 is a top view of a gas supply unit illustrated in FIG. 1.

FIG. 3 is an exploded perspective view of the gas supply unit illustrated in FIG. 1.

FIG. 4 is a front perspective view of an inject cap illustrated in FIG. 3.

FIG. 5 is a cross-sectional view of the inject cap illustrated in FIG. 4 when viewed from direction “A-B”.

FIG. 6 is an enlarged perspective view of a plurality of baffles illustrated in FIG. 1.

FIG. 7 is a top view of the baffles illustrated in FIG. 6.

FIG. 8 is a side view of the baffles illustrated in FIG. 6.

FIG. 9 is an exploded perspective view illustrating the inject cap and the baffles.

FIG. 10 is an assembled perspective view of the inject cap and the baffles illustrated in FIG. 9.

FIG. 11 is a cross-sectional view of the inject cap and the baffles when viewed from direction according to the embodiment.

FIG. 12 is a cross-sectional view of an inject cap and a plurality of baffles when viewed from direction “A-B” according to another example of the embodiment.

FIG. 13 is a view illustrating the flow of source gas when a typical epitaxial reactor includes an inject cap, a baffle, and an insert.

FIG. 14 is a view illustrating the flow of source gas when the epitaxial reactor of the embodiment includes an inject cap, a plurality of baffles, and an insert.

FIG. 15 is a view illustrating the flow velocity of source gas flowing in an inject cap, a plurality of baffles, and an insert.

FIG. 16 is a view illustrating the flow of source gas depending on the depth to which a plurality of baffles is inserted into an inject cap.

### BEST MODE

Reference will now be made in detail to the exemplary embodiments of the present disclosure, examples of which are illustrated in the accompanying drawings. It will be understood that when a layer (film), a region, a pattern, or an element is referred to as being “on” or “under” another layer (film), region, pattern, or, element, it can be directly on/under the layer, region, pattern, or, element, and one or more intervening elements may also be present. When an element is referred to as being “on” or “under”, “under the element” as well as “on the element” can be included based on the element.

In the drawings, the size of each layer is exaggerated, omitted, or schematically illustrated for convenience of description and clarity. Also, the size of each constituent element does not entirely reflect the actual size thereof. In addition, the same reference numbers will be used throughout the drawings to refer to the same or like parts. Hereinafter, an epitaxial reactor according to embodiments will be described with reference to the accompanying drawings.

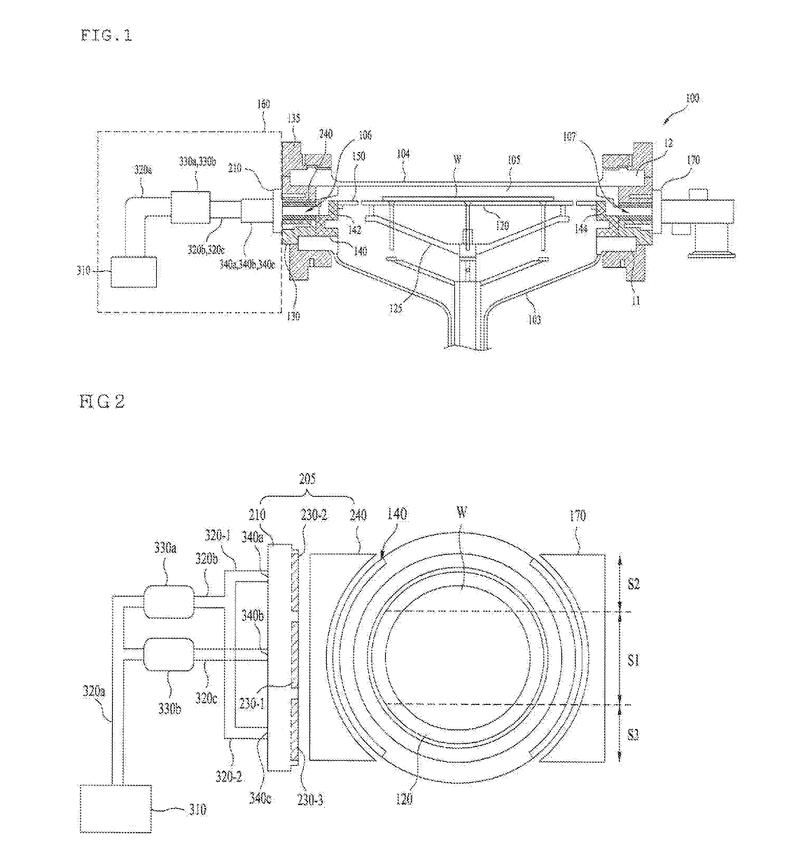

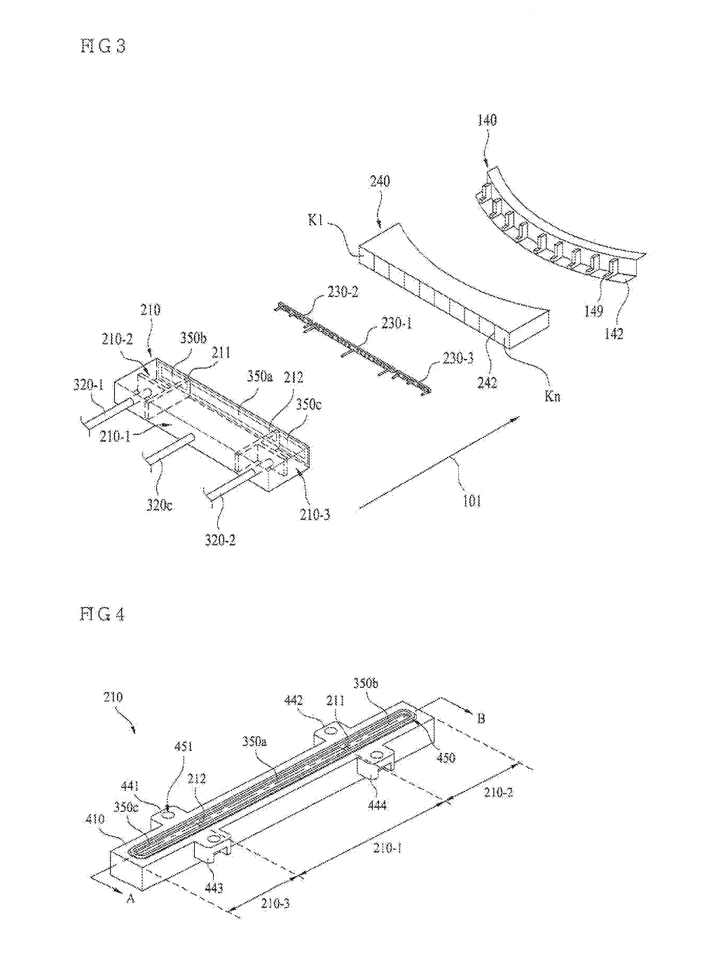

FIG. 1 is a cross-sectional view illustrating an epitaxial reactor 100 according to an embodiment. FIG. 2 is a top view of a gas supply unit 160 illustrated in FIG. 1. FIG. 3 is an exploded perspective view of the gas supply unit 160 illustrated in FIG. 1.

Referring to FIGS. 1 to 3, the epitaxial reactor 100 may be a single wafer processing type epitaxial reactor which processes semiconductor wafers one by one, and may include a reaction chamber 105 configured of a lower dome 103 and an upper dome 104, a susceptor 120, a susceptor support unit 125, a lower ring 130, an upper ring 135, a liner 140, a preheating ring 150, a gas supply unit 160, and a gas discharge unit 170.

The lower and upper domes 103 and 104 may be located so as to face each other in the vertical direction, and each may be made of a transparent material such as quartz glass. The reaction chamber 105 in which an epitaxial reaction occurs may be formed in a space between the lower and upper domes 103 and 104. The reaction chamber 105 may have a gas introduction port 106 formed at one side thereof such that source gas is introduced through the gas inlet port 106, and a gas discharge port 107 formed at the other side thereof such that the introduced source gas is discharged through the gas discharge port 107.

The susceptor 120 may be a support plate having a flat circular shape. The susceptor 120 may be disposed within the reaction chamber 105, and a wafer W may be seated on the upper surface of the susceptor 120. The susceptor 120 may be made of carbon graphite or a material in which carbon graphite is coated with silicon carbide.

The susceptor support unit 125 may be disposed beneath the susceptor 120 to support the susceptor 120, and may move the susceptor 120 vertically within the reaction chamber 105. The susceptor support unit 125 may include a tripodal shaft which supports the lower surface or the susceptor 120.

The liner 140 may be disposed so as to surround the susceptor 120. The liner 140 may have a first stepped part 142 formed at one side of the upper end of the outer peripheral surface thereof for introducing gas into the reaction chamber 105, and a second stepped part 144 formed at the other side of the upper end of the outer peripheral surface thereof for discharging the gas from the reaction chamber 105. The upper portion of the outer peripheral surface of the liner 140 may be flush with the upper surface of the susceptor 120 or the upper surface of the wafer W.

The lower ring 130 may be disposed so as to surround the liner 140, and may have a ring shape. One end 11 of the outer peripheral portion of the lower dome 103 may be pressed against and fixed to the lower ring 130.

The upper ring 135 may be located above the lower ring 130, and may have a ring shape. One end 12 of the outer peripheral portion of the upper dome 104 may be pressed against and fixed to the upper ring 135. Each of the lower and upper rings 130 and 135 may be made of quartz (SiO₂) or silicon carbide (SiC).

The preheating ring 150 may be disposed along the inner peripheral surface of the liner 140 adjacent to the susceptor 120 so as to be flush with the upper surface of the susceptor 120 or the upper surface of the wafer W.

The gas supply unit supplies source gas into the reaction chamber 105 from the outside. That is, the gas supply unit 160 may supply source gas to the gas introduction port 106 of the reaction chamber 105.

The gas supply unit 160 may include a gas generation part 310, a plurality of gas pipes (e.g., 320a, 320b, and 320c), gas regulation parts 330a and 330b, and a gas flow controller 205.

The gas flow controller 205 may include an inject cap 210, a plurality of baffles 230-1 to 230-3, and an insert 240.

The gas generation part 310 may generate source gas. For example, the source gas may be silicon compound gas such as SiHCl₃, SiCl₄, SiH₂Cl₂, SiH₄, and Si₂H₆, dopant gas such as B₂H₆ and PH₃, carrier gas such as H₂, N₂, and Ar, or the like.

The source gas generated by the gas generation part 310 may be supplied to the inject cap 210 through the gas pipes (e.g., 320a, 320b, and 320c).

The gas regulation parts 330a and 330b may regulate an amount of gas that is supplied to or flows in at least one of the gas pipes (e.g., 320a, 320b, and 320c), and may independently control the flow of source gas supplied to each of a central region S1 and edge regions S2 and S3 of the wafer W. The gas regulation parts 330a and 330b may be embodied, for example, by a mass flow controller.

The source gas generated by the gas generation part 310 may be individually supplied to a plurality of parts of the inject cap 210 through the gas pipes (e.g., 320a, 320b, and 320c). In this case, the number of gas pipes and the number of parts are not limited to those illustrated in FIG. 2, but may be two or more.

At least one (e.g., 320a or 320b) of the gas pipes (e.g., 320a, 320b, and 320c) may be divided into two or more gas pipes. The source gas may be supplied to the inject cap 210 through the divided gas pipes and be non-divided gas pipe.

For example, a first gas pipe 320a may be divided into a second gas pipe 320b and a third gas pipe 320c in order to individually supply source gas (or reaction gas) to each of the central region S1 and edge regions S2 and S3 of the wafer. In addition, the second gas pipe 320b may be divided into two gas pipes in order to individually supply source gas to each of both edge regions S2 and S3 of the wafer, so that the source gas is supplied to the inject cap.

The inject cap 210, the baffles 230-1 to 230-3, and the insert 240 may be sequentially arranged between the gas pipes (e.g., 320a, 320b, and 320c) and the liner 140. The source gas supplied from a plurality of gas pipes (e.g., 320-1, 320-2, and 320c) may flow through the inject cap 210, the baffles 230-1 to 230-3, and the insert 240 in turn.

The inject cap 210 may be partitioned into at least two parts (e.g., 210-1, 210-2, and 210-3) which are isolated from each other. Any one of a plurality of gas outlets (e.g., 350a, 350b, and 350c) may be provided in a corresponding one of the at least two parts (e.g., 210-1, 210-2, and 210-3). Although the inject cap 210 is depicted as being partitioned into three parts 210-1, 210-2, and 210-3 in FIGS. 1 and 2, the present disclosure is not limited thereto.

The inject cap 210 may include a plurality of gas inlets 340a, 340b, and 340c formed at one surface thereof such that source gas is introduced through the gas inlets 340a, 340b, and 340c from the gas pipes (e.g., 320-1, 320-2, and 320c), and a plurality of gas outlets (e.g., 350a, 350b, and 350c) formed at the other surface thereof such that the introduced source gas is discharged through the gas outlets 350a, 350b, and 350c.

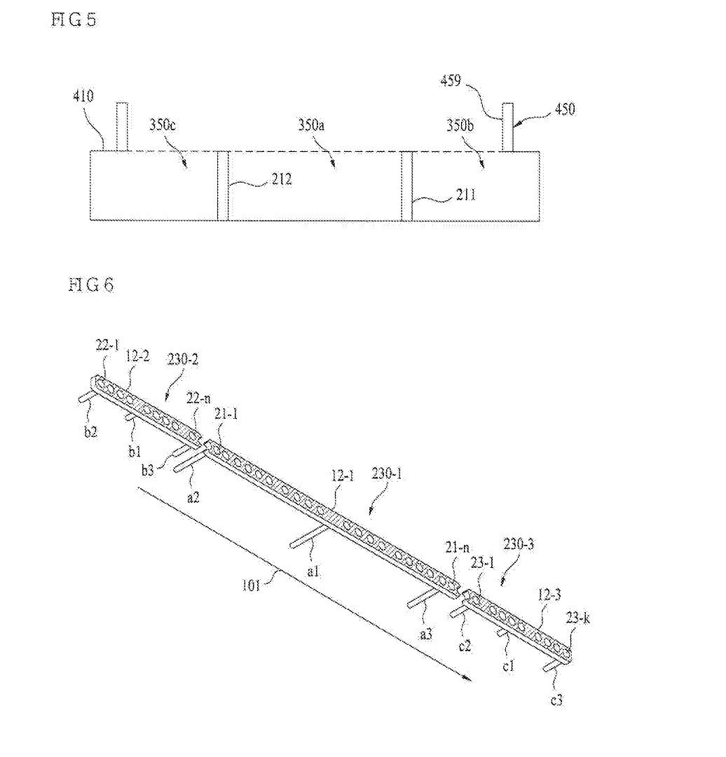

FIG. 4 is a front perspective view of the inject cap 210 illustrated in FIG. 3. FIG. 5 is a cross-sectional view of the inject cap 210 illustrated in FIG. 4 when viewed from direction “A-B”.

Referring to FIGS. 3 to 5, the gas outlets 350a, 350b, and 350c for discharging source gas may be provided at one surface 410 of the inject cap 210.

The inject cap 210 may include at least two parts (e.g., 210-1 to 210-3) which are separated or isolated from each other.

For example, a first part 210-1 may be located at the center of the inject cap so as to correspond to or be aligned with the central region S1 of the wafer W. For example, a second part 210-2 may be located at one side of the first part 210-1 so as to correspond to or be aligned with a first edge region S2 positioned at one side of the central region S1 of the wafer W. For example, a third part 210-3 may be located at the other side of the first part 210-1 so as to correspond to or be aligned with a second edge region S3 positioned at the other side of the central region S1 of the wafer W.

The first part 210-1 may have the gas inlet 340b through which source gas is introduced from a third gas pipe 320c, and the gas outlet 350a through which the introduced gas is discharged.

The second part 210-2 may have the gas inlet 340a through which source gas is introduced from a first gas pipe 320-1, and the gas outlet 350b through which the introduced gas is discharged.

The third part 210-3 may have the gas inlet 340c through which source gas is introduced from a second gas pipe 320-2, and the gas outlet 350c through which the introduced gas is discharged.

The inject cap 210 may include partitions between the adjacent parts for partitioning them. For example, the inject cap 210 may include a first partition 211 for partitioning the first and second parts 210-1 and 210-2, and a second partition 212 for partitioning the first and third parts 210-1 and 210-3. For example, source gas may independently flow in each of the parts 210-1, 210-2, and 210-3 owing to the partitions 211 and 212.

The inject cap 216 may have a guide part 450 which protrudes from one surface 410 thereof to expose the gas outlets 350a, 350b, and 350c. The guide part 450 may serve to support and guide the baffles 230-1 to 230-3 which are inserted or fitted into the guide part 340.

For example, the guide part 450 may have a closed loop or ring shape so as to surround the gas outlets 350a, 350b, and 350c. Alternatively, the guide part 450 may include a plurality of portions which are spaced apart from each other. The portions may be spaced around the gas outlets 350a, 350b, and 350c and be arranged in a ring form. That is, the shape of the guide part 450 is not limited to that described above. For example, the guide part 450 may have a groove into which the outer peripheral surfaces of the plates 12-1 to 12-3 of the baffles 230-1 to 230-3 are fixedly fitted.

Each of the baffles 230-1 to 230-3 may be inserted or fitted into the guide part 450 so as to be aligned with a corresponding one of the gas outlets 350a, 350b, and 350c.

The inject cap 210 may have one or more coupling parts 441 to 444 formed on the other surface thereof. The coupling parts 441 to 444 may have respective grooves 451 through which screws or bolts (not shown) are coupled. The screws or bolts may be coupled to the lower and upper rings 130 and 135, illustrated in FIG. 1, via the grooves 451.

The insert may be disposed so as to be inserted between the lower ring 130 and the upper ring 135, and may include a plurality of sections k1 to kn (n being a natural number greater than 1) through which gas may pass.

The insert 240 may include a partition wall 242 located between two adjacent sections, and the sections k1 to kn (n being a natural number greater than 1) may each be independent and may be isolated from each other by the partition walls 242.

Through-holes formed in any one of the baffles 230-1 to 230-3 may correspond to or be aligned with at least one of the sections k1 to kn (n being a natural number greater than 1).

Each of the sections k1 to kn in being a natural number greater than 1) of the insert 240 may have an opening area, which is greater than that of each of through-holes 21-1 to 21-n, 22-1 to 22-m, or 23-1 to 23-k (n, m, and k being natural numbers greater than 1) formed in each of the baffles 230-1 to 230-3, and smaller than that of each of first to third gas outlets 350a, 350b, and 350c.

The first stepped part 142 of the liner 140 may be provided with partition walls 149 corresponding to the partition walls 242 for partitioning the sections k1 to kn (n being a natural number greater than 1).

The source gas passing through the sections k1 to kn (n being a natural number greater than 1) may flow along the surface of the first stepped part 142 of the liner 140 which is separated or partitioned by the partition walls 149. The source gas introduced into the reaction chamber 105 through the surface of the first stepped part 142 may flow along the surface of the wafer W. The source gas passing through the surface of the wafer W may flow to the gas discharge unit 170 through the second stepped part 144 of the liner 140.

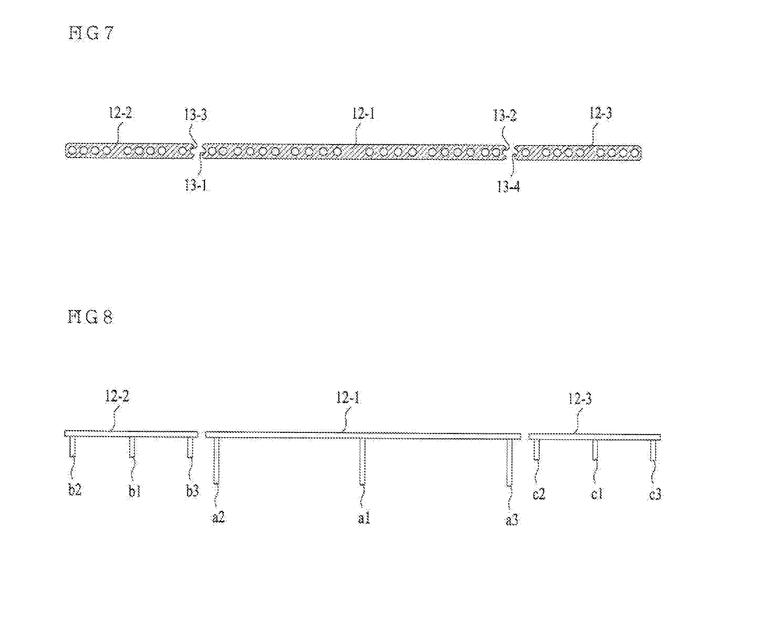

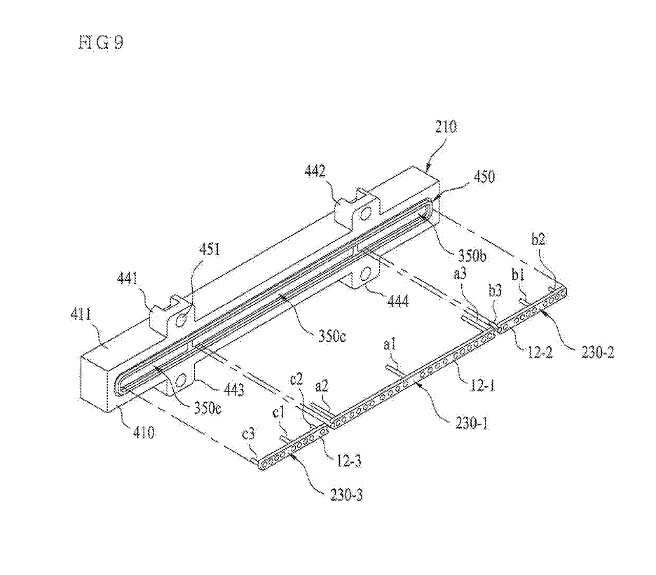

FIG. 6 is an enlarged perspective view of the baffles 230-1 to 230-3 illustrated in FIG. 1. FIG. 7 is a top view of the baffles 230-1 to 230-3 illustrated in FIG. 6. FIG. 8 is a side view of the baffles 230-1 to 230-3 illustrated in FIG. 6.

Referring to FIGS. 6 to 8, each of the baffles 230-1 to 230-3 may include a plate 12-1, 12-2, or 12-3, through-holes 21-1 to 21-n, 22-1 to 22-m, or 23-1 to 23-k (n, m, and k being natural numbers greater than 1), and a support part (e.g., a1 to a3, b1 to b3, or c1 to c3).

The plate 12-1, 12-2, or 12-3 may have a shape that is inserted or fitted into the guide part 450. The plate 12-1, 12-2, or 12-3 may have a size which is proportional to the size of a corresponding one of the gas outlets 350a to 350c in the inject cap 210. In addition, the plates 12-1, 12-2, and 12-3 of the baffles 230-1 to 230-3 may also have different sizes.

The through-holes 21-1 to 21-n, 22-1 to 22-m, or 23-1 to 23-k (n, m, and k being natural numbers greater than 1) may be provided so as to pass through the associated plate 12-1, 12-2, or 12-3, and may be arranged in a line at intervals in the longitudinal direction 101 of the plate 12-1, 12-2, or 12-3.

The through-holes 21-1 to 21-n, 22-1 to 22-n, or 23-1 to 23-k (n, m, and k being natural numbers greater than 1) may have the same diameter, but the present disclosure is not limited thereto. That is, alternatively, at least one of the through-holes may have a different diameter.

For example, the number of through-holes in a first baffle 230-1 may be 21, and the number of through-holes in each of second and third baffles 230-2 and 230-3 may be 9.5. However, the number of through-holes in each baffle is not limited thereto.

For example, each of the through-holes 21-1 to 21-n, 22-1 to 22-m, or 23-1 to 23-k (n, m, and k being natural numbers greater than 1) may have a diameter of 2 to 6 mm.

The support part (e.g., a1 to a3, b1 to b3, or c1 to c3) may be connected to one surface of the associated plate 12-1, 12-2, or 12-3, and may serve to support each of the baffles 230-1 to 230-3.

The support part (e.g., a1 to a3, b1 to b3, or c1 to c3) may include a plurality of legs which are connected to one surface of the plate 12-1, 12-2, or 12-3 and are located at intervals. The support part may have various shapes, so long as the flow of source gas is not disturbed. For example, the support part may have a shape of a cylindrical leg that is connected to the edge of the plate.

The plurality of legs a1 to a3, b1 to b3, or c1 to c3 may be located so as to be spaced apart from the through-holes 21-1 to 21-n, 22-1 to 22-m, or 23-1 to 23-k (n, m, and k being natural numbers greater than 1).

Although the legs are depicted as being respectively connected to one end, the other end, and the central portion of each plate 12-1, 12-2, or 12-3 in FIGS. 6 to 8, the present disclosure is not limited thereto. For example, the number of legs may be two or more.

For example, the first baffle 230-1 may be disposed so as to correspond to the gas outlet 350a, and may include the plate 12-1, the through-holes 21-1 to 21-n (n being a natural number greater than 1), and the legs a1 to a3. In the embodiment, the numbers of through-holes and legs are not limited to those illustrated in FIG. 6.

One end or both ends of each plate 12-1, 12-2, or 12-3 may be provided with a recessed groove(s) 13-1, 13-2, 13-3, or 13-4 in the longitudinal direction of the plate 12-1, 12-2, or 12-3.

For example, both ends of a first plate 12-1 located at the center of the baffles may be provided with recessed grooves 13-1 and 13-2 in the longitudinal direction of the plate 12-1, 12-2, or 12-3, and the respective ends of second and third plates 12-2 and 12-3 may be provided with recessed grooves 13-3 and 13-4 in the longitudinal direction of the plate 12-1, 12-2, or 12-3. Each of the grooves 13-1 to 13-4 may have a semicircular shape, but the present disclosure is not limited thereto.

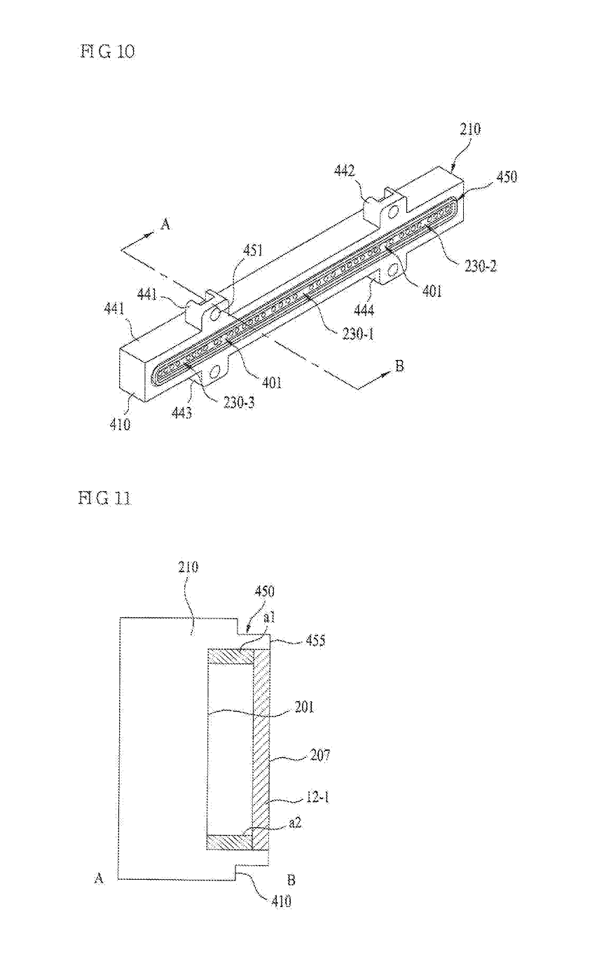

The groove (e.g., 13-1) provided in one end of one 12-1 of two adjacent plates (e.g., 12-1 and 12-2) and the groove (e.g., 13-3) provided in one end of the other 12-2 may be disposed adjacent to each other. Two adjacent grooves 13-1 and 13-3 may form one coupling groove 401 (see FIG. 10). In this case, the coupling groove 401 may have a circular shape, but the present disclosure is not limited thereto.

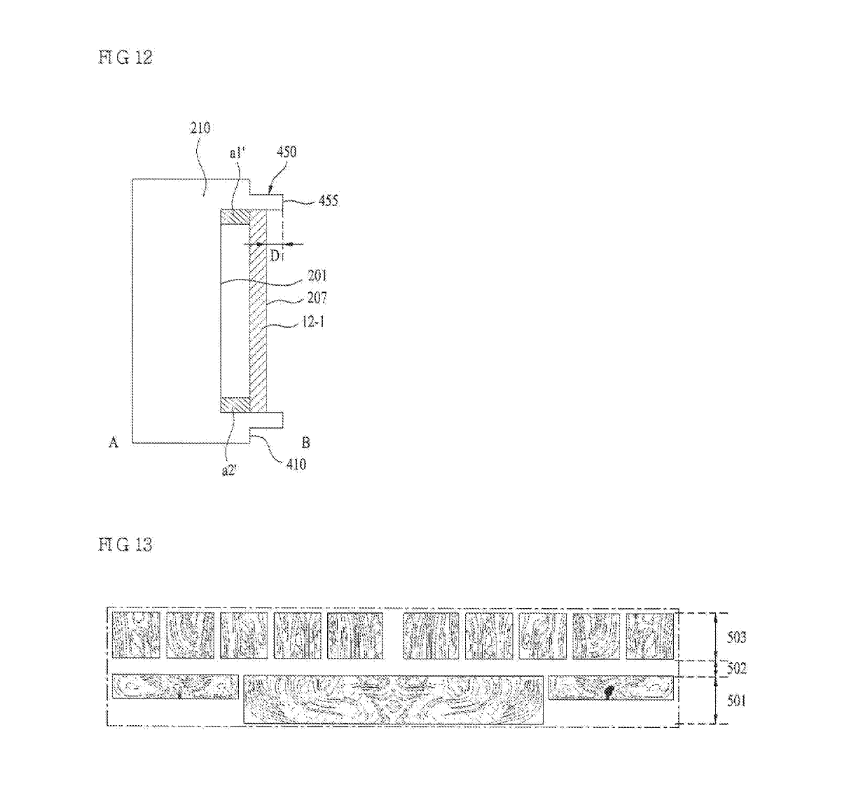

FIG. 9 is an exploded perspective view illustrating the inject cap 210 and the baffles 230-1 to 230-3. FIG. 10 is an assembled perspective view of the inject cap 210 and the baffles 230-1 to 230-3 illustrated in FIG. 9. FIG. 11 is a cross-sectional view of the inject cap 210 and the baffles 230-1 to 230-3 when viewed from direction “A-B” according to the embodiment.

Referring to FIGS. 9 to 11, the baffles 230-1 to 230-3 may be inserted or fitted into the guide part 450 such that the through-holes 21-1 to 21-n, 22-1 to 22-m, or 23-1 to 23-k (n, m, and k being natural numbers greater than 1) in each of the baffles 230-1 to 230-3 face a corresponding one of the gas outlets 350a, 350b, and 350c.

The legs a1 to a3, b1 to b3, or c1 to c3 of each of the baffles 230-1 to 230-3 may be inserted into a corresponding one of the gas outlets 350a, 350b, and 350c. In addition, the plates 12-1, 12-2, and 12-3 of the baffles 230-1 to 230-3 may be inserted or fitted into the guide part 450.

The outer peripheral surfaces of the baffles 230-1 to 230-3 inserted into the guide part 450 may be pressed against or come into contact with an inner wall 459 (see FIG. 5) of the guide part 450. For example, the outer peripheral surfaces of the plates 12-1, 12-2, and 12-3 of the baffles 230-1 to 230-3 inserted into the guide part 450 may be pressed against or come into contact with the inner wall 459 (see FIG. 5) of the guide part 450.

The ends of the legs a1 to a3, b1 to b3, and c1 to c3 inserted into the gas outlets 350a, 350b, and 350c may come into contact with an inner bottom 201 of the inject cap 210.

Upper surfaces 207 of the baffles 230-1 to 230-3, configured such that the ends of the legs a1 to a3, b1 to b3, and c1 to c3 come into contact with the inner bottom 201 of the inject cap 210, may be flush with an upper surface 455 of the guide part 450.

FIG. 12 is a cross-sectional view of an inject cap 210 and a plurality of baffles 230-1 to 230-3 when viewed from direction “A-B” according to another example of the embodiment.

Referring to FIG. 12, the depths of the baffles 230-1 to 230-3, which are inserted or fitted into a guide part 450, may be adjusted by adjusting the lengths of legs a1 to a3, b1 to b3, or c1 to c3 of each of the baffles 230-1 to 230-3.

For example, the lengths of the legs of one support part of the baffles 230-1 to 230-3 may differ from the lengths of the legs of the other support parts of the baffles 230-1 to 230-3.

For example, upper surfaces 207 of the baffles 230-1 to 230-3 configured such that the ends of the legs a1 to a3, b1 to b3, and c1 to c3 come into contact with an inner bottom 201 of the inject cap 210 may be located beneath an upper surface 455 of the guide part 450. A step D may be present between the upper surface 207 of each of the baffles 230-1 to 230-3 and the upper surface 455 of the guide part 450.

Since the baffles 230-1 to 230-5 corresponding to the individual parts 210-1 to 210-3 of the inject cap 210 are inserted into the guide part 450 in the embodiment, the baffles 230-1 to 230-3 may be stably fixed to the guide part 450. In addition, since the outer peripheral surfaces of the inserted baffles 230-1 to 230-3 are pressed against the inner wall of the guide part 450 in the embodiment, it is possible to minimize the formation of vortices when source gas passes through the inject cap 210 and the baffles 230-1 to 230-3.

In order to prevent source gas from staying or flowing backward in the inject cap 210, the step D between the upper surface 207 of each of the baffles 230-1 to 230-3 and the upper surface 455 of the guide part 450 may be less than 6 mm.

FIG. 16 is a view illustrating the flow of source gas depending on the depth to which a plurality of baffles is inserted into an inject cap. FIG. 16(a) illustrates the case where the step D between the upper surface 207 of each of the baffles 230-1 to 230-3 and the upper surface 455 of the guide part 450 is zero (D=0), and FIG. 16(b) illustrates the case where the step D between the upper surface 207 of each of the baffles 230-1 to 230-3 and the upper surface 455 of the guide part 450 is 6 mm.

Referring to FIG. 16, it may be seen that a stagnation region 701 of source gas is present and a back flow 702 of source gas occurs in FIG. 16(b), unlike FIG. 16(a). This is because the inside of the inject cap 210 is relatively small when the step D is equal to or larger than 6 mm, and thereby source gas stays or flows backward.

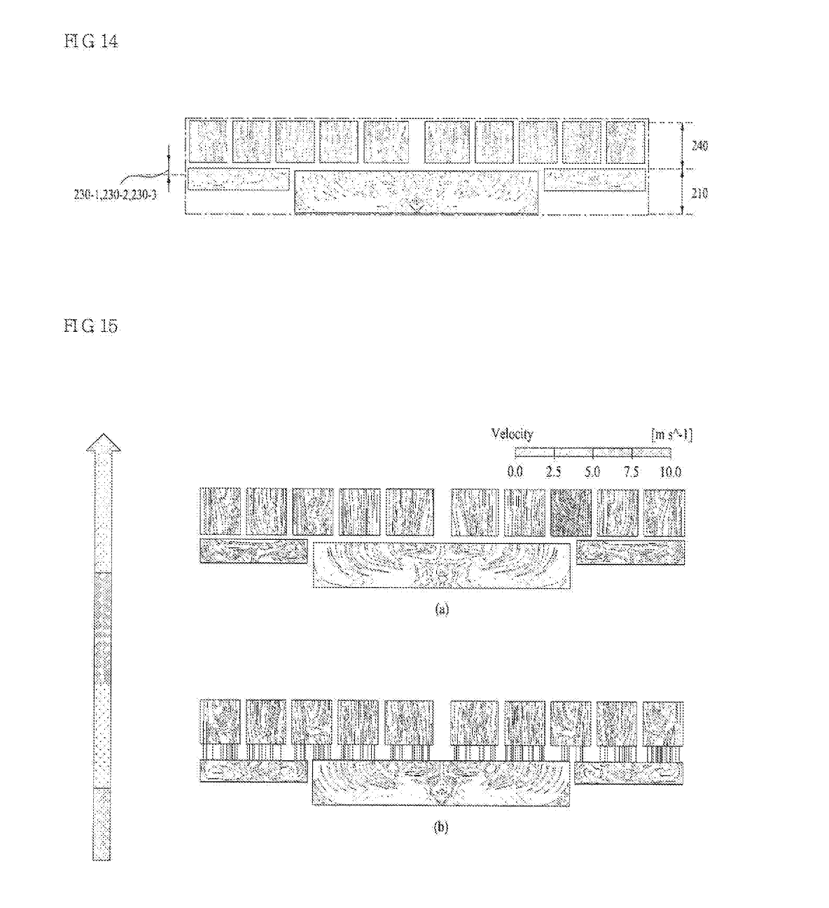

FIG. 13 is a view illustrating the flow of source gas when a typical epitaxial reactor includes an inject cap 501, a baffle 502, and an insert 503. FIG. 14 is a view illustrating the flow of source gas when the epitaxial reactor of the embodiment includes the inject cap 210, the baffles 230-1 to 230-3, and the insert 240.

FIG. 13 illustrates a typical gas supply unit in which the integral baffle 502 is disposed between the inject cap 501 and the insert 503. In FIG. 13, it may be seen that vortices are frequently formed and the flow of source gas is concentrated. This is because vortices may be increased and unstable flow may be caused while source gas flows into the baffle 502 from the inject cap 501. Here, “unstable flow” may mean that source gas flows to an undesired place with the consequence that the flow velocity of gas varies.

However, in the embodiment, each of the baffles 230-1 to 230-3 is disposed adjacent to a corresponding one of the gas outlets 350a, 350b, and 350c, as illustrated in FIG. 14. Therefore, the formation of vortices can be minimized in the flowing source gas and the flow of source gas can be stable.

In the embodiment, the baffles 230-1 to 230-3 inserted into the guide part 450 are arranged adjacent to the gas outlets 350a, 350b, and 350c. Accordingly, since source gas is uniformly supplied to the central region S1 and edge regions S2 and S3 of the wafer W in the reaction chamber 105, it is possible to increase the uniformity of thickness of the growing epilayer.

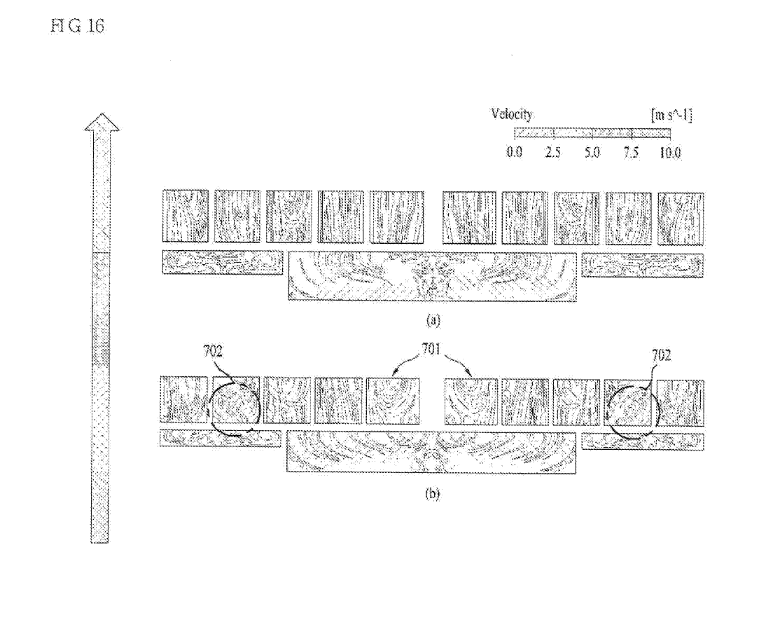

FIG. 15 is a view illustrating the flow velocity of source gas flowing in an inject cap, a plurality of baffles, and an insert. FIG. 15(a) illustrates the flow velocity of source gas in the embodiment, and FIG. 15(b) illustrates the flow velocity of source gas in a typical case in which an integral baffle is disposed on an inject cap.

Referring to FIG. 15, it may be seen that the flow (a) of source gas is more uniform and the flow velocity thereof is faster in the embodiment, compared to the flow (b) of source gas in the typical case. Therefore, in the embodiment, it is possible to increase the growth rate, owing to the fast flow velocity of source gas, and thereby to improve productivity.

Particular features, structures, or characteristics described in connection with the embodiment are included in at least one embodiment of the present disclosure and not necessarily in all embodiments. Furthermore, the particular features, structures, or characteristics of any specific embodiment of the present disclosure may be combined in any suitable manner with one or more other embodiments or may be changed by those skilled in the art to which the embodiments pertain. Therefore, it is to be understood that contents associated with such combination or change fall within the spirit and scope of the present disclosure.

### INDUSTRIAL APPLICABILITY

Embodiments are applicable to wafer manufacturing processes.

1. An epitaxial reactor comprising:
a reaction chamber;
a susceptor located in the reaction chamber such that a wafer is seated thereon; and
a gas flow controller for controlling a flow of gas introduced into the reaction chamber,
wherein the gas flow controller comprises:
an inject cap having a plurality of gas outlets for separating the flow of gas; and
a plurality of baffles, each having through-holes corresponding to a respective one of the gas outlets, and
wherein the baffles are separated from each other, and each of the baffles is disposed adjacent to a corresponding one of the gas outlets.

2. The epitaxial reactor according to claim 1, wherein:
the inject cap has a guide part protruding from one surface thereof to expose the gas outlets; and
the baffles are inserted into the guide part.

3. The epitaxial reactor according to claim 2, wherein the guide part has a ring shape so as to surround the gas outlets.

4. The epitaxial reactor according to claim 1, wherein each of the baffles comprises a plate having therein the through-holes spaced apart from each other, and a support part connected to one surface of the plate, the support part is inserted into each of the gas outlets, and the plate is inserted into a guide part.

5. The epitaxial reactor according to claim 4, wherein the support part comprises a plurality of legs spaced apart from each other, and the legs ate inserted into the associated gas outlet.

6. The epitaxial reactor according to claim 4, wherein an outer peripheral surface of the plate inserted into the guide part is pressed against an inner wall of the guide part.

7. The epitaxial reactor according to claim 5, wherein one end of the support part inserted into the gas outlet is in contact with an inner bottom of the inject cap.

8. The epitaxial reactor according to claim 4, wherein:
the plate has a recessed groove(s) formed in one end or both ends thereof in a longitudinal direction of the plate; and
the groove formed in one end of one of two adjacent plates inserted into the guide part and the groove formed in one end of a remaining one thereof are adjacent to each other, and the two adjacent grooves form one coupling groove.

9. The epitaxial reactor according to claim 7, wherein an upper surface of each of the baffles, configured such that one end of the support part comes into contact with the inner bottom of the inject cap, is flush with an upper surface of the guide part.

10. The epitaxial reactor according to claim 7, wherein an upper surface of each of the baffles, configured such that one end of the support part comes into contact with the inner bottom of the inject cap, is located beneath an upper surface of the guide part, and a step is present between the upper surface of each of the baffles and the upper surface of the guide part.

11. The epitaxial reactor according to claim 1, wherein:
the inject cap comprises at least two parts isolated from each other; and
one of the gas outlets is provided in a corresponding one of the at least two parts.

12. The epitaxial reactor according to claim 1, further comprising:
an insert comprising a plurality of sections separated from each other so that the gas passing through the through holes passes through the sections; and
a liner having a stepped part in order to guide the gas passing through the sections to the reaction chamber.

13. The epitaxial reactor according to claim 10, wherein the step is less than 6 mm.

14. The epitaxial reactor according to claim 2, wherein the guide part has a groove into which outer peripheral surfaces of the baffles are fixedly fitted.

15. The epitaxial reactor according to claim 2, wherein the baffles are inserted into the guide part such that each of the baffles is aligned with a corresponding one of the gas outlets.

16. The epitaxial reactor according to claim 2, wherein the inject cap has at least one coupling part formed at the other surface thereof.

17. The epitaxial reactor according to claim 5, wherein the legs of one support part of the baffles have different lengths from those of remaining support parts of the baffles.
